(19) United States
(12) Patent Application Publication
(10) Pub. No.: US 2024/0371676 A1
(43) Pub. Date: Nov. 7, 2024

(54) SEMICONDUCTOR PROCESSING EQUIPMENT AND CARRIER DEVICE THEREOF

(71) Applicant: BEIJING NAURA MICROELECTRONICS EQUIPMENT CO., LTD., Beijing (CN)

(72) Inventors: Xiqiang TIAN, Beijing (CN); Hua YE, Beijing (CN); Zhiyong CHEN, Beijing (CN); Chong WANG, Beijing (CN); Lei ZHU, Beijing (CN)

(21) Appl. No.: 18/768,381

(22) Filed: Jul. 10, 2024

Related U.S. Application Data
(63) Continuation of application No. PCT/CN2022/086320, filed on Apr. 12, 2022.

(30) Foreign Application Priority Data
Jan. 12, 2022 (CN) 202210031074.6

(51) Int. Cl. H01L 21/683; C23C 16/44; C23C 16/458

(52) U.S. Cl. CPC H01L 21/6833; C23C 16/4408; C23C 16/4585

(57) ABSTRACT

A carrier device applied to semiconductor processing equipment includes a base, a carrier element, and a position-limiting ring. The base includes a connection flow channel. a top surface of the base is configured to carry a wafer. The carrier element is stacked with the base and located under the base, a gas flow channel structure is formed between the carrier element and the base. A position-limiting ring structure is sleeved at an outer circumference of the base and configured to limit a position of the wafer. A gas blow cannel and a first uniform flow space are formed between an inner circumferential wall of the position-limiting ring structure and an outer circumferential wall of the base. The first uniform flow space communicates with the gas blow channel.

### CROSS-REFERENCE TO RELATED APPLICATIONS

This application is a continuation of International Application No. PCT/CN2022/086320, filed on Apr. 12, 2022, which claims priority to Chinese Application No. 202210031074.6 filed on Jan. 12, 2022, the entire contents of both of which are incorporated herein by reference.

### TECHNICAL FIELD

The present disclosure generally relates to the semiconductor manufacturing technology field and, more particularly, to a semiconductor processing equipment and a carrier device thereof.

### BACKGROUND

Currently, Chemical Vapor Deposition (CVD) is a process that generates a solid film on a surface of a wafer through a gas chemical reaction. A carrier device configured to carry the wafer for a thin film deposition process usually includes an edge purge function, which is used to blow away reaction gases near a back and sides of the wafer to avoid back plating and side plating of the wafer. As requirements for process temperature, metal contamination, and particles increase, a material of a top plate of the carrier device configured to carry the wafer is changed from metal aluminum and stainless steel to ceramic material with high-temperature resistance, good particle performance, and less metal contamination.

However, due to the difficulty in processing the top plate made of the ceramic material, it is difficult to form a pipe structure configured to perform edge purging in the top plate. Thus, the manufacturing cost is high, and the requirement of uniformly blowing gas at the wafer edge cannot be satisfied in the thin film deposition process. Therefore, the product quality cannot be ensured.

### SUMMARY

The present disclosure is intended to solve one of the technical problems in the existing technology and provides an electrostatic chuck and a base, which can reduce the manufacturing difficulty and the cost of the multi-wafer electrostatic chuck and improve the RF coupling efficiency and the semiconductor processing efficiency.

To realize the above purpose, the present disclosure provides a carrier device applied to semiconductor processing equipment and including a base, a carrier element, and a position-limiting ring. The base includes a connection flow channel. a top surface of the base is configured to carry a wafer. The carrier element is stacked with the base and located under the base, a gas flow channel structure is formed between the carrier element and the base. A position-limiting ring structure is sleeved at an outer circumference of the base and configured to limit a position of the wafer. A gas blow cannel and a first uniform flow space are formed between an inner circumferential wall of the position-limiting ring structure and an outer circumferential wall of the base. The first uniform flow space communicates with the gas blow channel. The gas flow channel structure communicates with the first uniform flow space via the connection flow channel and is configured to transfer a purge gas to the first uniform flow space via the connection flow channel. The first uniform flow space is configured to uniform the purge gas passing by. The gas blow channel is configured to blow the uniformed purge gas to purge a bottom surface and a side surface of the wafer.

The present disclosure further provides semiconductor processing equipment including a processing chamber and a carrier device. The carrier device includes a base, a carrier element, and a position-limiting ring. The base includes a connection flow channel. a top surface of the base is configured to carry a wafer. The carrier element is stacked with the base and located under the base, a gas flow channel structure is formed between the carrier element and the base. A position-limiting ring structure is sleeved at an outer circumference of the base and configured to limit a position of the wafer. A gas blow cannel and a first uniform flow space are formed between an inner circumferential wall of the position-limiting ring structure and an outer circumferential wall of the base. The first uniform flow space communicates with the gas blow channel. The gas flow channel structure communicates with the first uniform flow space via the connection flow channel and is configured to transfer a purge gas to the first uniform flow space via the connection flow channel. The first uniform flow space is configured to uniform the purge gas passing by. The gas blow channel is configured to blow the uniformed purge gas to purge a bottom surface and a side surface of the wafer.

### BRIEF DESCRIPTION OF THE DRAWINGS

The above and/or additional aspects and advantages of the present disclosure become apparent and easily understood according to the following description of embodiments in conjunction with the accompanying drawings.

FIG. 1 illustrates a schematic cross-section diagram of a carrier device according to some embodiments of the present disclosure.

FIG. 2 illustrates a schematic structural diagram of a bottom surface of a base according to some embodiments of the present disclosure.

FIG. 3 illustrates a schematic cross-section diagram of a carrier device according to some embodiments of the present disclosure.

FIG. 4A illustrates a schematic diagram showing a position relationship between a carrier device and a processing chamber according to some embodiments of the present disclosure.

FIG. 4B illustrates a schematic structural diagram of a top surface of a support shaft according to some embodiments of the present disclosure.

FIG. 5 illustrates a schematic cross-section diagram of a carrier device according to some embodiments of the present disclosure.

FIG. 6 illustrates a schematic structural diagram of a top surface of a base according to some embodiments of the present disclosure.

FIG. 7 illustrates a schematic structural diagram of a top surface of a carrier member according to a second embodiment of the present disclosure.

FIG. 8 illustrates a schematic local cross-section diagram of the carrier device in FIG. 1.

FIG. 9A illustrates a schematic diagram of a gas flow field simulation result of a second gas uniform space according to some embodiments of the present disclosure.

FIG. 9B illustrates a schematic diagram of a gas flow field simulation result of a first gas uniform space according to some embodiments of the present disclosure.

FIG. 9C illustrates a schematic diagram of a gas flow field simulation result of a flow-limiting channel according to some embodiments of the present disclosure.

FIG. 9D illustrates a schematic diagram of a gas flow field simulation result of a gas blowing channel according to some embodiments of the present disclosure.

FIG. 10 illustrates a schematic cross-section diagram of a carrier device according to some embodiments of the present disclosure.

FIG. 11 illustrates a schematic local enlarged cross-section diagram of a carrier device according to some embodiments of the present disclosure.

FIG. 12 illustrates a schematic local enlarged cross-section diagram of a carrier device according to some embodiments of the present disclosure.

FIG. 13 illustrates a schematic structural diagram of a bottom surface of a base according to some embodiments of the present disclosure.

FIG. 14 illustrates a schematic structural diagram of a top surface of a carrier member according to some embodiments of the present disclosure.

FIG. 15 illustrates a schematic structural diagram of a top surface of a carrier member according to some embodiments of the present disclosure.

FIG. 16A illustrates a schematic diagram of a gas flow field simulation result of a second uniform space according to some embodiments of the present disclosure.

FIG. 16B illustrates a schematic diagram of a gas flow field simulation result of a first uniform space according to some embodiments of the present disclosure.

FIG. 16C illustrates a schematic diagram of a gas flow field simulation result of a gas limiting channel according to some embodiments of the present disclosure.

FIG. 16D illustrates a schematic diagram of a gas flow field simulation result of a gas blowing channel according to some embodiments of the present disclosure.

### DETAILED DESCRIPTION OF THE EMBODIMENTS

The present disclosure is described in detail. Examples of embodiments of the present disclosure is shown in the accompanying drawings. Same or similar reference numbers always represent identical or similar members or members with identical or similar functions. Additionally, if the detailed description of the well-known technology is unnecessary for the illustrated features of the present disclosure the detailed description of the well-known technology can be omitted. Embodiments described below with reference to the accompanying drawings are exemplary and can only be used to describe the present disclosure and cannot be explained as limiting to the present disclosure.

Those skilled in the art can understand, unless otherwise specified, all terms used here (including technical and scientific terms) have the same meaning as generally understood by those ordinary skill in the art. Those terms defined in a general dictionary can be understood to have the consistent meaning with the meaning of the context of the existing technology. Unless specified here, those terms will not be explained overly idealized or overly formal.

The technical solution of the present disclosure and how the above technical problem is solved using the technical solution of the present disclosure are described in detail below.

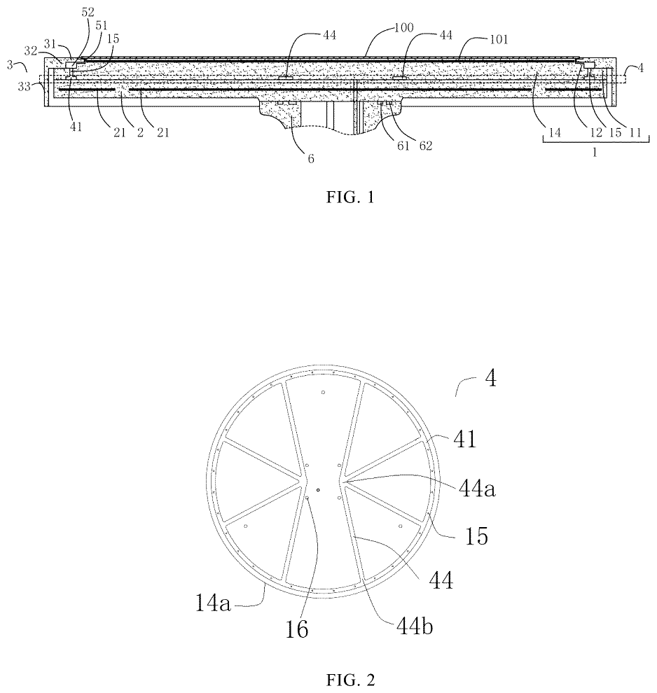

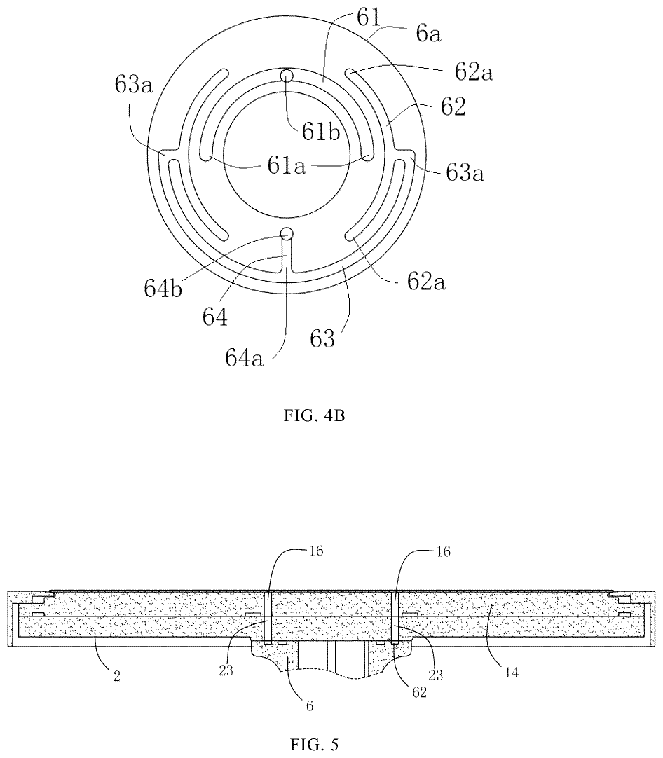

Embodiments of the present disclosure provide a carrier device of semiconductor processing equipment. The carrier device can be arranged in a processing chamber (e.g., a processing chamber 7 in FIG. 4A). The structure of the carrier device is shown in FIG. 1 and includes a base 1, a carrier element 2, and a position-limiting ring structure 3. A top surface of the base 1 is configured to carry a wafer 100. In some embodiments, the base 1 includes a base body 14. A top surface of the base body 14 is configured to carry the wafer 100. The position-limiting ring structure 3 is sleeved at the outer circumference of the base 1 and configured to limit the position of the wafer 100. A gas blow channel 51 and a first uniform flow space 52 are formed between an inner circumferential wall of the position-limiting ring structure 3 and an outer circumferential wall of the base 1. The first uniform flow space 52 communicates with the gas blow channel 51. The carrier element 2 overlaps with the base 1 and is arranged under the base 1. A gas flow structure 4 is formed between the carrier element 2 and the base 1. A connection flow channel 15 is formed in the base 1. The gas flow structure 4 can be configured to transfer the purge gas to the first uniform flow space 52 via the connection flow channel 15. The first uniform flow space 52 can be configured to uniform the flow for the purge gas passing by. The gas blow channel 51 can be configured to blow the uniformed purge gas out to blow the bottom surface and side surfaces (i.e., exposed parts at the edge of the wafer 100) of the wafer 100.

As shown in FIG. 1, the semiconductor processing equipment is configured to perform a chemical vapor deposition process on the wafer 100. However, embodiments of the present disclosure are not limited to this. Those skilled in the art can adjust accordingly as needed. The base 1 can be made of a ceramic material with a circular plate structure. The top surface of the base 1 can be configured to carry the wafer 100. The diameter of the top surface of the base 1 can be smaller than the diameter of the wafer 100. In some embodiments, a radio frequency (RF) grounded electrode 101 can be also arranged at the base 1 and be configured to be electrically connected to the RF power source or grounded. The carrier element 2 can be made of ceramic material into the circular plate structure. The carrier element 2 can be stacked by the base 1 and arranged at the bottom of the base 1 and can be arranged in the processing chamber through a support shaft 6. The support shaft 6 can ascend and descend. A lower end of the support shaft 6 can extend out from the bottom of the processing chamber to be connected to an external ascending and descending drive source. Bellows are sleeved at the support shaft 6 and configured to seal a gap between the support shaft 6 and the processing chamber to ensure the sealing ability of the processing chamber. In some embodiments, the carrier element 2 can include a heating pipe 21 configured to heat the wafer 100. The heating pipes 21 can be arranged at different areas of the carrier element 2. For example, as shown in FIG. 1, two heating pipes 21 are provided and are arranged correspondingly at a center area and an edge area of the carrier element 2, respectively to control the temperature at divided areas. Moreover, the gas flow structure 4 can be arranged between the carrier element 2 and the base 1. The gas flow structure 4 can be configured to be connected to the gas source to introduce the purge gas and transfer the purge gas to the first flow uniform space 52. The position-limiting ring structure 3 can be a sleeve structure made of ceramic material. The position-limiting ring structure 3 can be sleeved at the outer circumference of the base 1 and configured to limit the position of the wafer 100 at the base 1. However, embodiments of the present disclosure are not limited to this. The gas blow channel 51 and the first uniform flow space 52 are formed between the inner circumferential wall of the position-limiting ring structure 3 and the outer circumferential wall of the base 1. For example, the gas blow channel 51 and the first flow uniform space 52 can be arranged sequentially from top to bottom. The top of the first uniform flow space 52 can communicate with the gas blow channel 51, and the bottom of the first uniform flow space 52 can communicate with the gas flow structure 4 through the connection flow channel 15 to be configured to introduce the purge gas to the gas flow structure 4 to uniform the flow. The gas blow channel 51 can be configured to blow the uniformed purge gas out to blow the bottom surface and the side surface of the wafer 100. Since the diameter of the top surface of the base 1 is smaller than the diameter of the wafer 100. Thus, the purge gas from the gas blow channel 51 can flow through the exposed area of the bottom surface and the side surface of the wafer 100 to uniformly blow the bottom surface and the side surface of the wafer 100.

In the carrier device of embodiments of the present disclosure, the position-limiting ring structure 3 is sleeved at the outer circumference of the base 1. The gas blow channel 51 and the first flow uniform space 52 can be formed between the inner circumferential wall of the position-limiting ring structure 3 and the outer circumferential wall of the base 1. The gas flow structure 4 can be formed between the bottom surface of the base 1 and the top surface of the carrier element 2. The gas flow structure 4 can be configured to transfer the purge gas to the first uniform flow space 52 via the connection flow channel 15 of the base 1. The first uniform flow space 52 can cause the purge gas entered the first uniform flow space 52 to diffuse faster along the circumferential direction of the base 1 to blow the bottom surface and the side surface of the wafer 100. The purge gas can be uniformed with the first uniform flow space 52. Thus, the gas blow channel 51 can uniformly blow the gas to ensure that the edge gas blowing can have the consistent impact on the bottom surface and the side surface of the wafer 100. Thus, the consistency of the process film can be greatly improved, and the process yield can be greatly improved. In addition, the gas blow channel 51 and the first uniform flow space 52 are formed between the base and the position-limiting ring structure, and the gas flow structure is formed between the base and the carrier element, the structure is simple and is conveniently manufactured, which greatly reduces the application and manufacturing cost.

In some embodiments, as shown in FIG. 1 and FIG. 2, the gas flow structure 4 includes a guide flow channel structure and a second uniform flow space 41. The guide flow channel structure communicates with the second uniform flow space 41. The second uniform flow space 41 communicates with the first uniform flow space 52 via the connection flow channel 15. In some embodiments, the second uniform flow space 41 can be in a ring shape and can be arranged opposite to the first uniform flow space 52 in a vertical direction. The volume of the second uniform flow space 41 can be larger than the volume of the first uniform flow space 52. The guide flow channel structure can be configured to transfer the purge gas to the second uniform flow space 41. The second uniform flow space 41 can be configured to uniform the purge gas flowing by. In some embodiments, the purge gas outputted by the guide flow channel structure can first be uniformed once by the second uniform flow space 41 and then be uniformed a second time by the first uniform flow space 52. Then, the gas blow channel 51 can blow the purge gas to the bottom surface and the side surface of the wafer 100. With the above design, since the purge gas is uniformed twice through two levels of uniform flow spaces, the purge gas out from the gas blow channel 51 can be more uniform. Thus, the purge uniformity at the wafer edge can be further improved, and the process uniformity and the process yield of the wafer can be further improved.

In addition, the second uniform flow space 41 can be closer to the gas source compared to the first uniform flow space 52. The purge gas can have a fast flow rate when entering the second uniform flow space 41 and may not be uniform. Thus, by causing the volume of the second uniform flow space 41 to be larger than the volume of the first uniform flow space 52, the first level flow uniform can be performed using the second uniform flow space 41 with the larger volume. Thus, the gas flow can be better buffered. Thus, after the buffer of the second uniform flow space 41, the purge gas can be better uniformed when entering the first uniform flow space 52. Thus, the uniformity of the purge gas can be improved.

In some embodiments, as shown in FIG. 1 and FIG. 8, a gas introduction cross-section of the connection flow channel 15 is smaller than the gas introduction cross-section of the first uniform flow space 52 and the second uniform flow space 41. In some embodiments, the connection flow channel 15 includes a plurality of flow-limiting holes passing through the base 1. The plurality flow-limiting holes can be uniformly arranged along the circumferential direction of the base 1. Two ends of each flow-limiting hole can communicate with the first uniform flow space 52 and the second uniform flow space 41, respectively. In some embodiments, the flow-limiting holes pass through the base 1 in the vertical direction.

The connection flow channel 15 can adopt a flow-limiting hole. Thus, the manufacturing can be simple in embodiments of the present disclosure, the yield can be greatly improved, and the application and maintenance costs can be further reduced. Further, the gas introduction cross-section of the connection flow channel 15 (i.e., the gas introduction cross-sections of the flow-limiting holes) can be smaller than the gas introduction cross-section of the first uniform flow space 52 and the gas introduction cross-section of the second uniform flow space 41. That is, the gas introduction cross-section of the connection flow channel 15 tangent to the gas flow direction can be smaller than the gas introduction cross-section of the first uniform flow space 52 tangent to the gas flow direction and the gas introduction cross-section of the second uniform flow space 41 tangent to the gas flow direction. Thus, the connection flow channel 15 can increase the pressure for the purge gas outputted from the second uniform flow space 41. In connection with the uniform function of the first uniform flow space 52, the uniformity of the purge gas can be further improved to increase the uniformity and yield of the wafer 100.

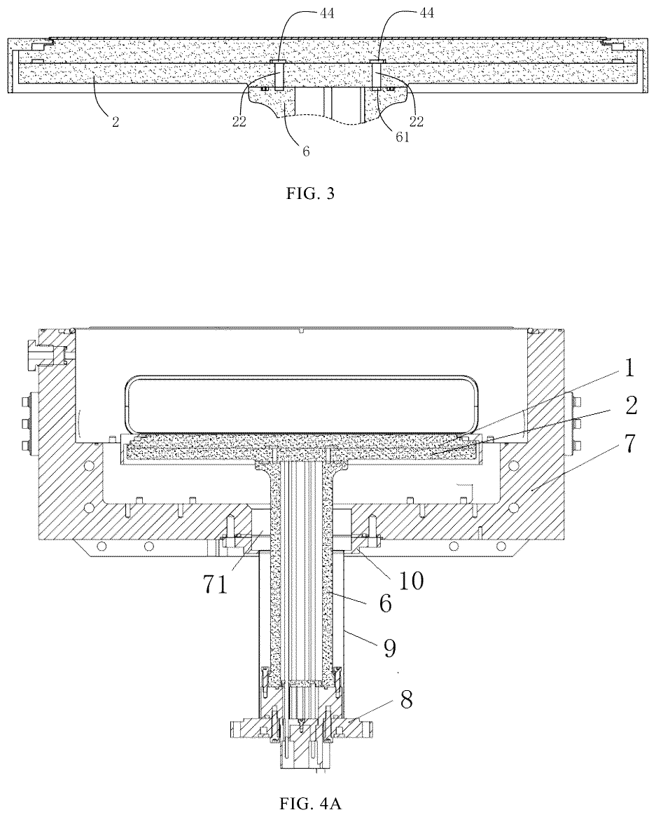

In some embodiments, as shown in FIG. 2 and FIG. 3, the guide flow channel structure includes at least one guide flow channel 44 and at least one gas through-hole 22 passing through the carrier element 2, Each gas through-hole 22 can communicate with an inlet end 44a of the at least one guide flow channel 44. The gas through-hole 22 can be configured to communicate with the purge gas source. With the gas through-holes 22, the purge gas can be introduced to at least one guide flow channel 44 and transfer the purge gas to the inlet ends 44a of the guide flow channels 44 simultaneously to ensure the uniformity of the purge gas.

Outlet ends 44b of the guide flow channels 44 can be arranged uniformly along the circumferential direction of the second uniform flow space 41 at intervals and can communicate with the second uniform flow space 41. For example, as shown in FIG. 3, two gas through-holes 22 are provided. In some embodiments, the two gas through-holes 22 can be arranged at or close to the center position of the base 1 and configured to communicate with the purge gas source. Each gas through-hole 22 can communicate with the inlet ends 44a of four guide flow channels 44. That is, the inlet ends 44a of the four guide flow channels 44 can converge at the same gas through-hole 22 and communicate with the gas through-hole 22. The four guide flow channels 44 can be arranged in the circumferential direction of the second uniform flow space 41 at intervals. The outlet ends 44b of the four guide flow channels 44 can communicate with the second uniform flow space 41. With the above structure, the guide flow channel structure can transfer the purge gas toward the edge position of the base 1 from the position close to the center position of the base 1 in different directions to reach different positions in the circumferential direction of the second uniform flow space 41. Thus, the path of the purge gas can be shortened, the flow rate of the purge gas can be improved, and the uniformity of the purge gas can be further improved.

In some embodiments, as shown in FIG. 2, four guide flow channels 44 communicating with one gas through-hole 22 of the gas through-holes 22 and four guide flow channels 44 communicating with another gas through-hole 22 of the gas through-holes 22 are symmetrically distributed about the axis. Lengths of the guide flow channels 44 (e.g., eight guide flow channels 44) can be nearly same. Outlet ends 44b of the guide flow channels 44 (i.e., eight outlet ends 44b) can be uniformly distributed in the circumferential direction of the second uniform flow space 41. Thus, the purge gas flowing into the guide flow channels 44 from the inlet ends 44a can flow to the outlet ends 44b along the paths with the same length and can flow uniformly into the second uniform flow space 41 from the outlet ends 44b. Thus, the uniformity of the purge gas can be further improved. In practical applications, three or more guide flow channel groups can be provided. The numbers and layouts of the gas through-holes 22 and the guide flow channels 44 are not limited in embodiments of the present disclosure. Those skilled in the art can adjust as needed.

In some embodiments, as shown in FIG. 2, an annular groove and a plurality of straight grooves are formed on a surface of the base 1 facing the carrier element 2 (i.e., the bottom surface 14a). the annular groove can cooperate with the surface of the carrier element 2 facing the base 1 (i.e., the top surface) to form the second uniform flow space 41. Each straight groove can cooperate with the surface of the carrier element 2 facing the base 1 (i.e., the top surface) to form the above guide flow channel 44. However, embodiments of the present disclosure are not limited to this. The annular groove and the plurality of straight grooves can also be formed on the surface of the carrier element 2 facing the base 1 (i.e., the top surface). The annular groove can cooperate with the surface of the base 1 facing the carrier element 2 (i.e., the bottom surface 14a) to form the second uniform flow space 41. Each straight groove can cooperate with the surface of the base 1 facing the carrier element 2 (i.e., the bottom surface 14a) to form the guide flow channel 44. In some other embodiments, annular grooves and a plurality of straight grooves can be formed on both of the surface of the base 1 facing the carrier element 2 (i.e., the bottom surface 14a) and the surface of the carrier element 2 facing the base 1 (i.e., the top surface). The annular groove on the surface of the base 1 facing the carrier element 2 (i.e., the bottom surface 14a) can cooperate with the annular groove on the surface of the carrier element 2 facing the base 1 (i.e., the top surface) to form the second uniform flow space 41. Each straight groove on the surface of the base 1 facing the carrier element 2 (i.e., the bottom surface 14a) can cooperate with a corresponding straight groove on the surface of the carrier element 2 facing the base 1 (i.e., the top surface) to form the guide flow channel 44.

In some embodiments, as shown in FIG. 3, FIG. 4A, and FIG. 4B, the carrier device further includes a support shaft 6. The support shaft 6 is located under the carrier element 2 and is configured to support the carrier element 2. In some embodiments, as shown in FIG. 4A, a through-hole 71 is formed at the bottom of the processing chamber 7. The lower end of the support shaft 6 can extend through the through-hole 71 to the outside of the processing chamber 7 to be connected to the ascending and descending drive source (not shown in the figure). In addition, the bellows 9 is provided at the outside of the processing chamber 7. The bellows 9 is sleeved at the support shaft 6. The lower end of the bellows 9 can be sealed and connected to a lower flange 8. The upper end of the bellows 9 can be sealed and connected to the bottom of the processing chamber 7 through an upper flange 10. The bellows 9 can be configured to seal the through-hole 71 to ensure the sealing inside the processing chamber 7.

A first uniform flow channel structure can be formed on the surface of the support shaft 6 facing the carrier element 2 (i.e., the top surface 6a). The first uniform flow channel structure can communicate with the inlet ends of the gas through-holes 22. The first uniform flow channel structure can communicate with the purge gas source. The first uniform flow channel structure can be configured to uniform the purge gas passing by. In some embodiments, the first uniform flow channel structure can include at least one first curved flow channel 61. The first curved flow channel 61 can extend along the circumferential direction of the support shaft 6. Each first curved flow channel 61 can be arranged and correspond to two through-holes 22. The inlet ends of the two through-holes 22 can communicate with two ends 61a of the first curved flow channel 61. An inlet opening 61b communicating with the purge gas source can be formed at the center position of the first curved flow channel 61. The purge gas provided by the purge gas source can first enter the first curved flow channel 61 from the inlet opening 61b of the first curved flow channel 61 and then divided to the two ends 61a of the first curved flow channel 61. Then, the purge gas can flow to the corresponding guide flow channels 44 through the corresponding two through-holes 22. The first curved flow channel 61 can uniform the purge gas passing by and cause the purge gas to flow to the through-holes 22 in the same path. Thus, the purge gas can be divided uniformly. In addition, at least one first curved flow channel 61 can be formed between the surface of the support shaft 6 facing the carrier element 2 (i.e., the top surface 6a) and the bottom surface of the carrier element 2 to further simplify the structure and reduce the manufacturing difficulty. Thus, the application and manufacturing costs can be greatly reduced.

In some embodiments, two through-holes 22 are provided, and one first curved flow channel 61 corresponds to the two through-holes 22. However, embodiments of the present disclosure are not limited to this. In practical applications, the number and layout of the first curved flow channels 61 can be set according to the number of the through-holes 22. Those skilled in the art can adjust as needed.

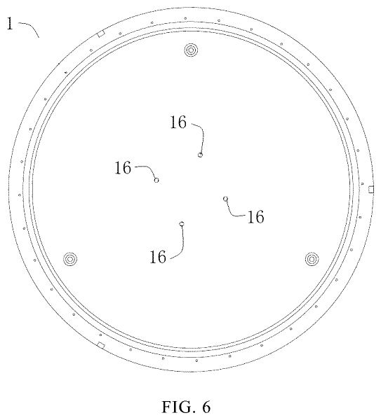

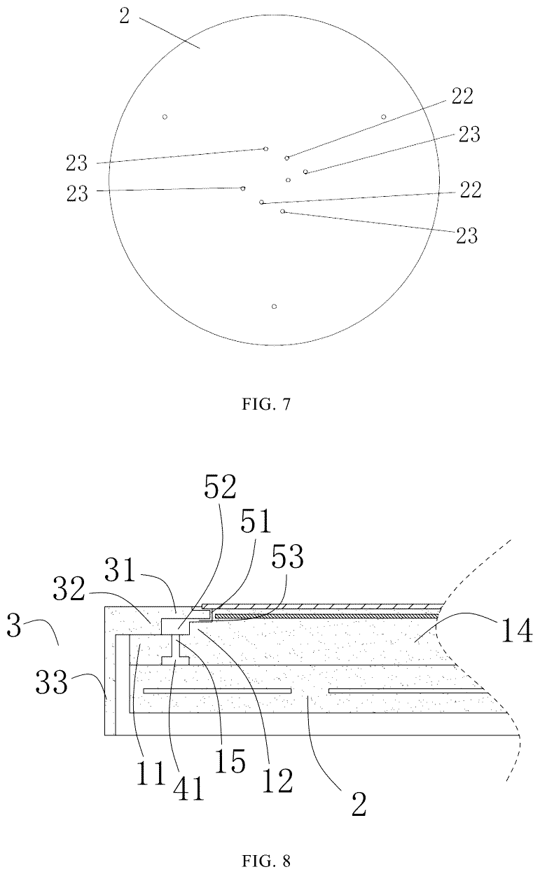

In some embodiments, as shown in FIG. 4A to FIG. 6, to realize a vacuum absorption function of the carrier device, a plurality of first absorption holes 16 passing through the base 1 are formed at the base 1 (e.g., the base body 14). For example, FIG. 6 shows four first absorption holes 16. The plurality of absorption holes 16 are distributed along the circumferential direction of the base 1. As shown in FIG. 7, a plurality of second absorption holes 23 passing through the carrier element 2 are formed at the carrier element 2. The number of the second absorption holes 23 can be the same as the number of the first absorption holes 16, and the second absorption holes 23 can be in a one-to-one correspondence with the first absorption holes 16. As shown in FIG. 4B, the second uniform flow channel structure is formed on the surface of the support shaft 6 facing the carrier element 2 (i.e., the top surface 6a). The second uniform flow channel structure can communicate with the inlet ends of the second absorption holes 23. The second uniform flow channel structure can communicate with the vacuum absorption device. The second uniform flow channel structure can be configured to uniform the gas passing by. In some embodiments, the second uniform flow channel structure can include at least one second curved flow channel 62. The second curved flow channel 62 can extend along the circumferential direction of the support shaft 6. As shown in FIG. 5, each second curved flow channel 62 can correspond to two second absorption holes 23. The inlet ends of the two second absorption holes 23 can communicate with the two ends 62a of the second curved flow channel, respectively. An inlet opening communicating with the vacuum absorption device is formed at the center position of the second curved flow channel 62. For example, four second absorption holes 23 are provided. As shown in FIG. 4, each two absorption holes 23 correspond to a second curved flow channel 62. Thus, two second curved flow channels 62 are provided and are distributed symmetrically about the axis of the base 1. Thus, the second uniform flow channel structure can further include a third curved flow channel 63. The third curved flow channel 63 can extend along the circumferential direction of the support shaft 6. Two ends 63a of the third curved flow channel 63 can communicate with the two second curved flow channels 62 at the center positions of the two second curved flow channels 62. The third curved flow channel 63 can communicate with the vacuum absorption device at the center position of the third curved flow channel 63. For example, the third curved flow channel 63 can communicate with the vacuum absorption device through a straight channel 64. The outlet end 64a of the straight channel 64 can be connected to the center position of the third curved flow channel 63. The inlet end 64b of the straight channel 64 can communicate with the vacuum absorption device. In some embodiments, four second absorption holes 23 can be provided. Thus, the two second curved flow channels 62 and the one third curved flow channel 63 can be provided to correspond to the four second absorption holes 23. However, embodiments of the present disclosure are not limited to this. In practical applications, the numbers and layouts of the second curved flow channels 62 and the third curved flow channel 63 can be set according to the number of the second absorption holes 23. Those skilled in the art can adjust as needed. In addition, if one second curved flow channel 62 is provided, the third curved flow channel 63 can be omitted. In connection with the first curved flow channels 61, the second curved flow channels 62, and the third curved flow channel 63, the vacuum absorption gas path and the edge purge gas path can be isolated and can be uniformly divided.

In some embodiments, as shown in FIG. 1 and FIG. 8, the position-limiting ring structure 3 includes a ring body 33. A cover ring 31 that protrudes toward the base 1 (e.g., the base body 14) is formed at the inner circumferential wall of the ring body 33. A gap is provided between the inner circumferential wall of the cover ring 31 and the outer circumferential wall of the base 1 to form the gas blow channel 51. In some embodiments, the ring body 33 can include a circular sleeve structure. The cover ring 31 can be formed integrally at the top of the inner circumferential wall of the ring body 33. The inner circumferential wall of the cover ring 31 can surround the outer circumferential wall of the base 1 with a gap. The gas can be configured to form the ring-shaped gas blow channel 51. Since the diameter of the top surface of the base 1 is smaller than the diameter of the of the wafer 100, the purge gas from the gas blow channel 51 can flow through the exposed area of the bottom surface and the side surface of the wafer 100. Since the gas blow channel 51 is ring-shaped and surrounds the base 1 in the circumferential direction, the gas blow channels 51 can blow the purge gas simultaneously in the circumferential direction to uniformly purge the bottom surface and the side surface of the wafer 100. With the above design, the structure can be simple, the yield of the carrier device can be greatly increased, and the application and maintenance costs can be further reduced. Embodiments of the present disclosure do not limit the cover ring 31 and the position-limiting ring structure 3. For example, the cover ring 31 and the position-limiting ring structure 3 can be separated structures and can be fixed connected in a welding method. Embodiments of the present disclosure are not limited to this. Those skilled in the art can adjust as needed.

In some embodiments, as shown in FIG. 1 to FIG. 8, a support ring 11 protruding toward the inner circumferential wall of the ring body 33 is arranged at the outer circumferential wall of the base body 14. An overlap ring 32 protruding toward the base body 14 is formed in the area of the inner circumferential wall of the ring body 33 below the cover ring 31. The overlap ring 32 can be stacked on the support ring 11. The overlap ring 32 can have a gap with the outer circumferential wall of the base body 14 to form the first uniform flow space 52. In some embodiments, the inner diameter of the overlap ring 32 can be greater than the inner diameter of the cover ring 31. That is, the cover ring 31 and the overlap ring 32 can be formed integrally at the inner circumferential wall of the ring body 33 and form a step structure. Further, the relative position between the overlap ring 32 and the support ring 11 can be limited by a position-limiting structure. For example, the overlap ring 32 and the support ring 11 can be fixedly arranged using a pin. With the above design, the first uniform flow space 52 can be formed with the simple structure of embodiments of the present disclosure, which is easy to manufacture. The structure of embodiments of the present disclosure can be stable to extend the application life. The first uniform flow space 52 is not limited in embodiments of the present disclosure. For example, a groove can be formed on the inner circumferential wall of the ring body 33, or a groove can be formed on the outer circumferential wall of the base body 14. The two grooves can form the first uniform flow space 52 independently or cooperatively. Embodiments of the present disclosure are not limited to this, and those skilled in the art can adjust as needed.

In some embodiments, as shown in FIG. 1 to FIG. 8, a protruded flow-limiting ring 12 is arranged between the overlap ring 11 and the cover ring 31 on the outer circumferential wall of the base body 14. The flow-limiting ring 12 can have a gap with the cover ring 31 to form the flow-limiting channel 53. The flow-limiting channel 53 can be configured to communicate with the gas blow channel 51 and the first uniform flow space 52. In some embodiments, the flow-limiting ring 12 can be formed integrally at the outer circumferential wall of the base body 14. The flow-limiting ring 12 can be located at the top of the support ring 11. The outer diameter of the flow-limiting ring 12 can be smaller than the outer diameter of the support ring 11. That is, two level steps can be formed from top to bottom at the outer circumferential wall of the base body 14. The top surface of the flow-limiting ring 12 and the top surface of the support ring 11 can be step surfaces of the two level steps to cause the structure of embodiments of the present disclosure to be simple. Further, the inner circumferential wall of the overlap ring 32, the top surface of the support ring 11, the outer circumferential wall of the flow-limiting ring 12, and the bottom surface of the cover ring 31 can cooperate to form the first uniform flow space 52. A gap can be formed between the bottom surface of the cover ring 31 and the top surface of the flow-limiting ring 12. The gas can be configured to form the flow-limiting channel 53. An end of the flow-limiting channel 53 can communicate with the first uniform flow space 52. The other end of the flow-limiting channel 53 can communicate with the bottom of the gas blow channel 51. With the flow-limiting channel 53, the pressure of the purge gas from the first uniform flow space 52 can be increased to increase the uniform time of the purge gas in the first uniform flow space 52 to improve the uniform effect. Thus, the purge uniformity of the gas blow channel 51 can be improved, and the uniformity and the yield of the wafer can be further improved. the flow-limiting channel 53 is not limited in embodiments of the present disclosure. For example, a block structure can be arranged at a position where the gas blow channel 51 communicates with the first uniform flow space 52 and is configured to increase the internal pressure of the first uniform flow space 52 to improve the uniform effect. Embodiments of the present disclosure are not limited to this, and those skilled in the art can adjust as needed.

In some embodiments, as shown in FIG. 8, the gas introduction cross-section of the flow-limiting channel 53 is smaller than the gas introduction cross-section of the gas blow channel 51. The gas introduction cross-section of the gas blow channel 51 is smaller than the gas introduction cross-section of the first uniform flow space 52. In some embodiments, the gas introduction cross-section of the flow-limiting channel 53 can be smaller than the gas introduction cross-section of the gas blow channel 51, and the gas introduction cross-section of the gas blow channel 51 can be smaller than the gas introduction cross-section of the first uniform flow space 52. The gas introduction cross-sections are tangent to the gas flow direction to cause the gas flow pressure of the first uniform space 52 to be high. Thus, the uniform flow efficiency and the uniform flow effect can be further improved. In addition, in some embodiments, the gas introduction cross-section of the connection flow channel 15 can be smaller than the gas introduction cross-section of the first uniform flow space 52 and the gas introduction cross-section of the second uniform flow space 41 and larger than the gas introduction cross-section of the flow-limiting channel 53. Thus, the pressure of the second uniform flow space 41 can be increased to uniform the gas flow, and the flow rate can be increased to improve the edge purge efficiency. In practical applications, the connection flow channel 15 can be configured to increase the pressure of the purge gas in the second uniform flow space 41 to uniform the purge gas. Then, the purge gas can enter the first uniform flow space 52 through the connection flow channel 15. The flow-limiting channel 53 can be configured to increase the pressure of the purge gas in the first uniform flow space 52 to uniform the purge gas. Then, the bottom surface and the side surface of the wafer 100 can be purged through the flow-limiting channel 53 and the gas blow channel 51. In the application of the first uniform flow space 52, the second uniform flow space 41, the connection flow channel 15, and the flow-limiting channel 53, two levels of pressure increment can be realized to uniform the purge gas to further improve the uniformity of the purge gas and the uniformity and the yield of the wafer 100.

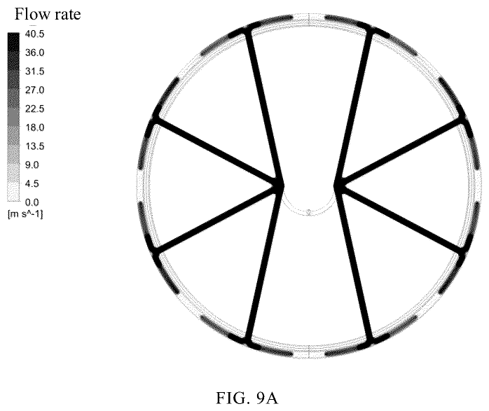

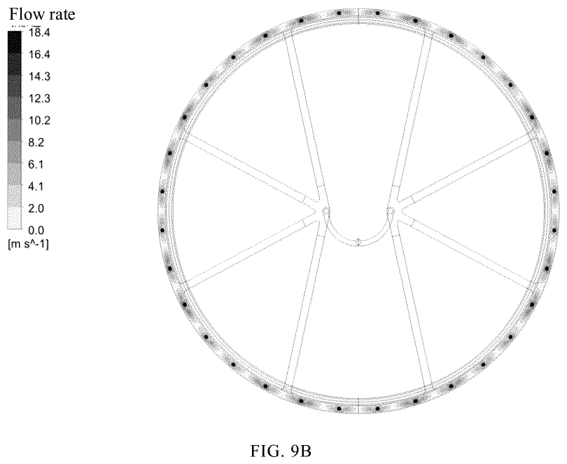

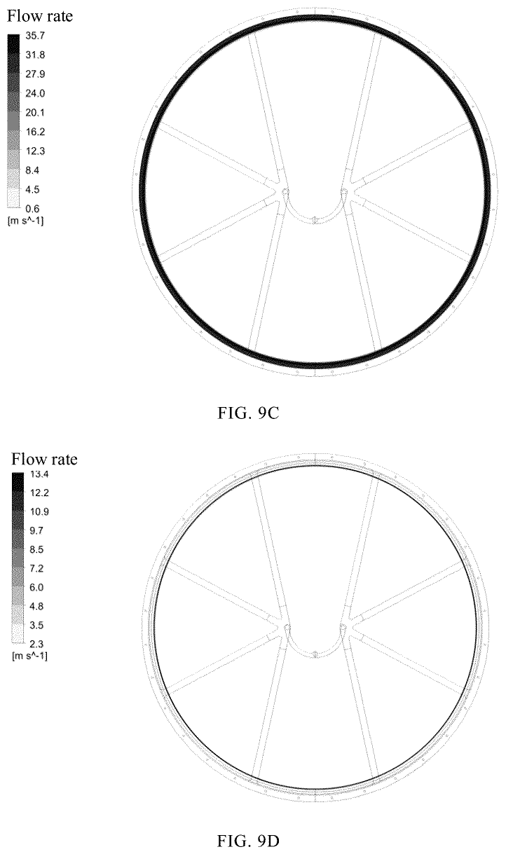

To further describe the beneficial effects of embodiments of the present disclosure, in connection with FIGS. 9A to 9D, a simulation test is performed. In some embodiments, for example, two through-holes 22 and eight guide flow channels 44 are provided to perform the gas field simulation test. The simulation results are shown in FIG. 9A. The purge gas can enter the guide flow channels 44 from the through-holes 22 with a high speed. After reaching the second uniform flow space 41, the purge gas can be uniformed. According to the simulation results, the gas flow distribution in the second uniform flow space 41 is not uniform. That is, the gas flow rate is large at the outlet opening of the guide flow channel 44, and the gas flow rate away from the outlet opening of the guide flow channel 44 is small, the differences between the flow rates of different areas of the second uniform flow space 41 is large, and the gas flow is not uniform. After being uniformed in the second uniform flow space 41, the pressure of the purge gas can be increased by the flow-limiting holes of the connection flow channel 15 and then enter the first uniform flow space 52. The purge gas can be uniformed again when reaching the first uniform flow space 52. The gas flow field simulation results in the first uniform flow space 52 are shown in FIG. 9B. the differences between the gas flow rates in the first uniform flow space 52 become smaller, and the gas flow becomes relatively uniform. Thus, the uniformity of the gas flow in the first uniform flow space 52 can be improved compared to the second uniform flow space 41, and the gas flow becomes relatively uniform. The pressure of the purge gas can be increased again through the flow-limiting channel 53. The gas flow simulation results of the flow-limiting channel 53 are shown in FIG. 9C, the gas flow can have a nearly consistent flow rate in the flow-limiting channel 53. The differences between the flow rates are small, and the gas is blown uniformly, as shown in the block part in FIG. 9C. The gas flow field simulation results after the purge gas reaches the gas blow channel 51 are shown in FIG. 9D. The flow rates of the gas flow can be nearly consistent in the gas blow channel 51. Thus, the gas blow channel 51 can purge the edge of the wafer uniformly.

In some embodiments, the base 1, the carrier element 2, and the position-limiting ring structure 3 can be made of an aluminum nitride ceramic material. In some embodiments, when the base, the carrier element 2, and the position-limiting ring structure 3 are made of the aluminum nitride ceramic material, the edge of the wafer 100 can be purged uniformly, the carrier device can have advantages such as high-temperature resistance, smaller particle pollution, and greatly reduced metal pollution. Thus, the yield of the wafer can be improved, and the process uniformity of the wafer can be improved. However, embodiments of the present disclosure are not limited to specific materials. For example, other types of ceramic materials can be used, as long as the above requirements can be satisfied. Embodiments of the present disclosure are not limited to this, and those skilled in the art can adjust as needed.

Embodiments of the present disclosure can further provide a carrier device of the semiconductor processing equipment. Compared to the carrier device above, the carrier device can also include the base 1, the carrier element 2, and the position-limiting ring structure 3, which have the same structures and functions as the above carrier device. Only the differences between the carrier device and the above carrier device are described in detail below.

In some embodiments, as shown in FIG. 10, the base 1 includes a heating pipe 13, which is configured to heat the wafer 100. Heating pipes 13 can be arranged at different areas of the base 1. For example, as shown in FIG. 10, two heating pipes 13 are provided and arranged correspondingly at the center area and the edge area of the base 1 to control the temperature in divided areas.

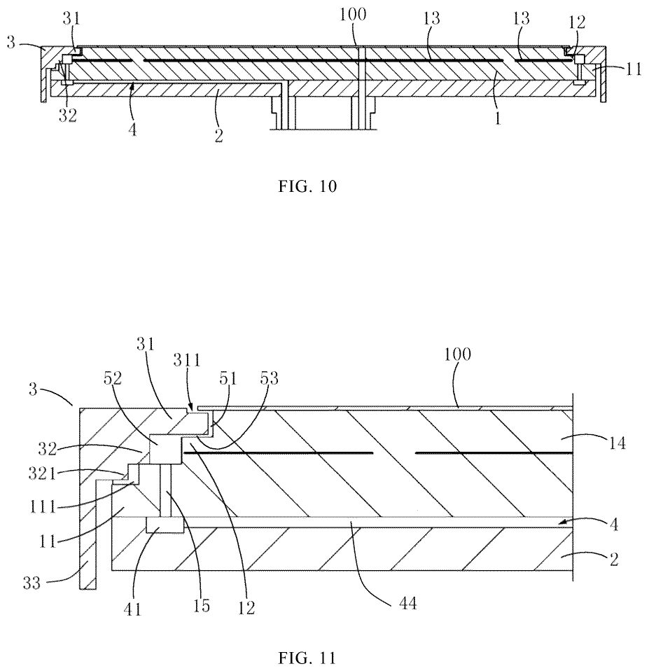

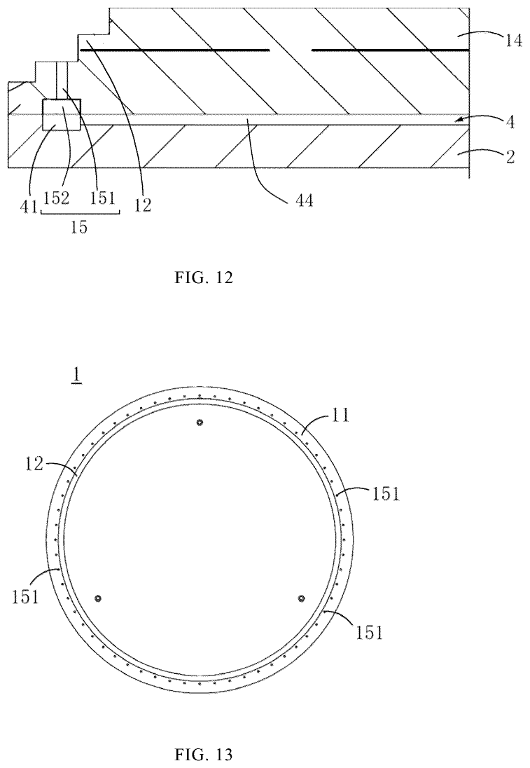

In some embodiments, as shown in FIG. 11, a guide flow groove 311 is formed at a connection position where the top surface of the cover ring 31 and the inner circumferential surface are connected. The guide flow groove 311 can be ring-shaped and surround the cover ring 31 in the circumferential direction. The bottom surface of the guide flow groove 311 can be lower than the top surface of the base 1 (e.g., the base body 14). The diameter of the circumferential side surface of the guide flow groove 311 can be greater than the diameter of the wafer 100. The guide flow groove 311 can communicate with the gas blow channel 51 and can be configured to guide the purge gas from the gas blow channel 51 to the bottom surface and the side surface of the wafer 100. In some embodiments, the guide flow groove 311 can be formed at a position of the cover ring 31 close to the inner circumferential wall. For example, an open groove can be formed between the top surface of the cover ring 31 and the inner circumferential wall and can be configured to form the guide flow groove 311. Further, the top surface of the cover ring 31 can be flush with the top surface of the base 1, and the bottom surface of the guide flow groove 311 can be lower than the top surface of the base 1. That is, when the top surface of the base 1 carries the wafer 100, the guide flow groove 311 can limit the wafer 100 at the inner side of the guide flow groove 311 and can form a guide flow gap with the bottom surface and the side surface of the wafer 100. When the purge gas of the gas blow channel 51 purges the bottom surface of the wafer 100, the guide flow groove 311 can guide the purge gas to the side surface to avoid back plating and side plating. That is, the film can be prevented from being deposited on the bottom surface and the side surface of the wafer 100 to improve the yield of the wafer 100. With the above design, the gas flow field can be more uniform, and the edge purging of the wafer 100 can be more uniform to further improve the uniformity and the process yield of the wafer 100. In embodiments of the present disclosure, the guide flow groove 311 is not necessary. For example, the top surface of the cover ring 31 can be lower than the top surface of the base 1 to form a gap between the cover sing 31 and the bottom surface of the wafer 100 to realize the similar function as the guide flow groove 311. Embodiments of the present disclosure are not limited to this, and those skilled in the art can adjust as needed.

In some embodiments, as shown in FIG. 11, the positioning structure is arranged between two surfaces of the overlap ring 32 and the support ring 11 that are staked with each other. The positioning structure includes a positioning convex member and a positioning recess member. The positioning convex member can cooperate with the positioning recess member to limit the relative position of the overlap ring 32 and the support ring 11 to position the position-limiting ring structure 3 and the base 1. In some embodiments, the position convex member can be, for example, a position convex block 321 protruding from the bottom surface of the overlap ring 32. The positioning recess member can be, for example, a positioning groove 111 formed at the top surface of the support ring 11. The positioning block 321 can cooperate with the positioning groove 111 to limit the relative position between the position-limiting ring structure 3 and the base 1.

In some embodiments, a plurality of positioning convex members can be provided, for example, three positioning convex members can be provided. The plurality of positioning convex members can be distributed along the circumferential direction of the support ring 11 uniformly at intervals. The number of the positioning recess members can be the same as the number of the positioning convex members, and the positioning recess members can be in a one-to-one correspondence with the convex members. With the above design, the stability between the position-limiting ring structure 3 and the base 1 can be improved, and the manufacturing difficulty can be reduced. Thus, the application life can be extended, and the assembly and disassembly maintenance cost can be greatly reduced. Embodiments of the present disclosure do not limit the implementation of the position-limiting structure, those of skilled in the art can adjust as needed.

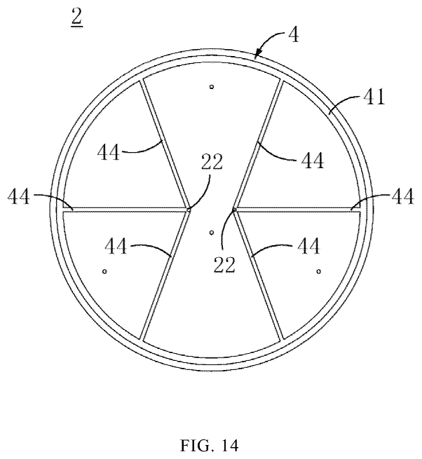

In some embodiments, as shown in FIG. 11 and FIG. 13, the flow-limiting holes of the connection flow channel 15 can be straight through-holes. However, embodiments of the present disclosure are not limited to this. For example, as shown in FIG. 12, each flow-limiting hole of the connection flow channel 15 includes a first straight through-hole 151 and a second straight through-hole 152 arranged sequentially along a vertical direction. The first straight through-hole 151 is over the second straight through-hole 152. The diameter of the first straight through-hole 151 is smaller than the diameter of the second straight through-hole 152. Since the diameter of the first straight through-hole 151 close to the top of the support ring 11 is smaller than the diameter of the second straight through-hole 152 close to the bottom of the support ring 11, i.e., the connection flow channel includes a structure with different diameters, the first straight through-hole 151 with the smaller diameter can further reduce the flow rate of the purge gas to enhance the pressure and the uniform flow effect of the purge gas in the second uniform flow space 41. Thus, the uniformity of the edge purge can be further improved.

In embodiments of the present disclosure, the structure of each flow-limiting hole in the connection flow channel 15 is not limited. For example, the flow-limiting hole can be a stepped hole with more steps or a conical hole configured to increase the pressure and limit the flow of the second uniform flow space 41. Thus, embodiments of the present disclosure are not limited to this, and those skilled in the art can adjust as needed.

In some embodiments, as shown in FIG. 11 and FIG. 14, the gas through-holes 22 pass through the carrier element 2. For example, two gas through-holes 22 are formed at the center position of the carrier element 2. Each gas through-hole 22 can communicate with the second uniform flow space 41 through the three guide flow channels 44 in a straight line. An end of each guide flow channel of the three guide flow channels 44 can communicate with the gas through-holes 22. The other end of each guide flow channel of the three guide flow channels 44 can communicate with the second uniform flow space 41. The guide flow channel 44 can communicate with the gas through-hole 43 and the second uniform flow space 41 in a straight line communication method. With the above design, since the plurality of gas through-holes 22 communicate with the second uniform flow space 41 through the plurality of guide flow channels 44. Thus, the path of the purge gas can be short, and the uniformity can be relatively good. Therefore, the flow rate of the purge gas can be improved, and the application cost and the maintenance costs of embodiments of the present disclosure can be greatly increased. In embodiments of the present disclosure, the numbers and the positions of the gas through-holes 22 and the guide flow channels 44 are not limited. Those skilled in the art can adjust as needed.

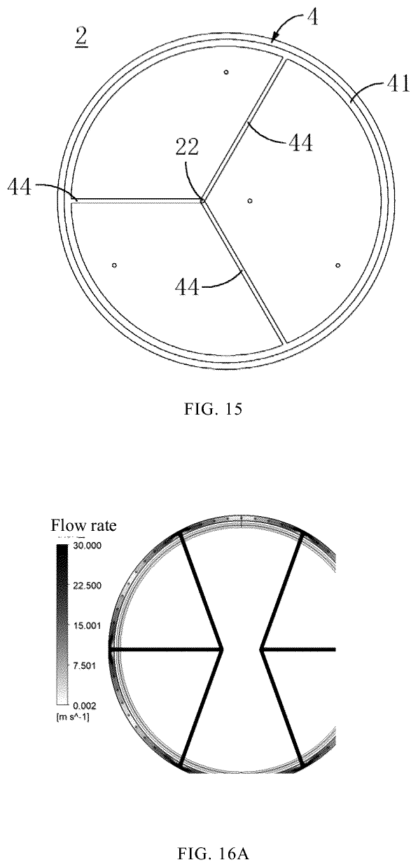

In some embodiments, as shown in FIG. 15, one gas through-hole 22 is provided and is located on a side of the center position of the carrier element 2. One end of each guide flow channel 44 of the three guide flow channels 44 communicates with the gas through-hole 22. The other end of each guide flow channel of the guide flow channels 44 communicates with the second uniform flow space 41. The other ends of the three guide flow channels 44 are arranged along the circumferential direction at intervals. Since the carrier element 2 is made of ceramic material, when the number of the gas through-holes 22 is reduced, the yield of the carrier element 2 can be further increased. Thus, the application and the maintenance costs of embodiments of the present disclosure are further reduced.

In some embodiments, as shown in FIG. 14, an annular groove and a plurality of straight grooves are formed on a surface of the carrier element 2 facing the base 1 (i.e., the top surface). the annular groove cooperates with the surface of the base 1 facing the carrier element 2 (i.e., the bottom surface) to form the second uniform flow space 41. Each straight groove can cooperate with the surface of the base 1 facing the carrier element 2 (i.e., the bottom surface) to form the guide flow channel 44. In some embodiments, an annular groove can be formed on the surface of the carrier element 2 facing the base 1 (i.e., the top surface). the annular groove can be arranged coaxially with the carrier element 2 and close to the edge of the carrier element 2. When the carrier element 2 is stacked at the bottom of the base 1, the annular groove can cooperate with the surface of the base 1 facing the carrier element 2 (i.e., the bottom surface) to form the second uniform flow space 41. With the design, the structure of embodiments of the present disclosure can be simple and easy to manufacture. Thus, the application and maintenance costs can be greatly reduced. Further, the plurality of straight grooves can be formed on the surface of the carrier element 2 facing the base 1 (i.e., the top surface). The straight grooves can be arranged between the gas through-holes 22 and the annular groove. The straight grooves can cooperate with the surface of the base 1 facing the carrier element 2 (i.e., the bottom surface) to form a plurality of guide flow channels 44 to be configured to communicate the gas through-holes 22 and the second uniform flow space 41. With the design, the structure of embodiments of the present disclosure can be easy to manufacture, and the application and maintenance costs can be greatly reduced. However, in embodiments of the present disclosure, the structures of the second uniform flow space 41 and the guide flow channel 44 are not limited. For example, the annular groove and the straight grooves can be formed on the surface of the base 1 facing the carrier element 2 (i.e., the bottom surface), or on both the surface of the base 1 facing the carrier element 2 (i.e., the bottom surface) and the surface of the carrier element 2 facing the base 1 (i.e., the top surface). Embodiments of the present disclosure are not limited to this, and those skilled in the art can adjust as needed.

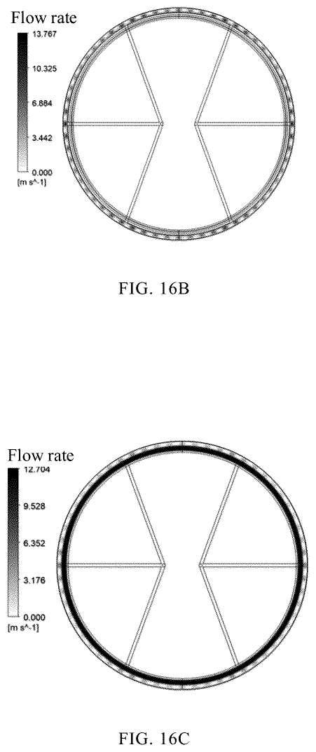

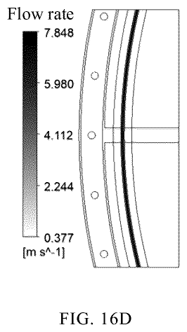

To further describe the beneficial effects of embodiments of the present disclosure, in connection with FIG. 16A to FIG. 16D, a simulation test can be performed in embodiments of the present disclosure. In some embodiments, a gas flow field simulation can be performed when two gas through-holes 22 and six guide flow channels 44 are provided as an example. The simulation results are shown in FIG. 16A. The purge gas enters the guide flow channel 44 via the gas through-hole 22 with a high speed. After reaching the second uniform flow space 41, the purge gas can be uniformed. However, according to the simulation result, the distribution of the gas flow in the second uniform flow space 41 is not uniform. That is, the gas flow rate is high at the gas outlet opening of the guide flow channel 44 and low away from the gas outlet opening of the guide flow channel 44. The flow rates at different areas of the second uniform space 41 can be quite different, and the gas flow is not uniform. After being uniformed in the second uniform flow space 41, the purge gas can enter the first uniform flow space 52 after the flow is limited and pressurized by the flow-limiting holes of the connection flow channel 15. The purge gas can be uniformed second time after reaching the first uniform flow space 52. The gas flow field simulation result in the first uniform flow space 52 is shown in FIG. 16B. the difference between the flow rates in the first uniform flow space 52 become smaller, and the gas flow becomes uniform. Thus, the uniformity of the gas flow in the first uniform flow space 52 is improved compared to the second uniform flow space 41, and the gas flow becomes relatively uniform. The flow is limited, and the purge gas is pressurized the second time by the flow-limiting channel 53. The gas flow field simulation result of the flow-limiting channel 53 is shown in FIG. 16C. the flow rate of the gas flow can be nearly consistent in the flow-limiting channel 53. As shown in the black part in FIG. 16C, the differences between the flow rates are small, and the gas blow is uniform. After the purge gas reaches the gas flow channel 51, the gas flow field simulation result is shown in FIG. 16D. The flow rates of the gas flow can be nearly consistent in the gas blow channel 51. Thus, the gas blow channel 51 can purge uniformly to the edge of the wafer.

In summary, in the carrier device of embodiments of the present disclosure, the position-limiting ring structure can be arranged at the outer circumferential sleeve of the base. The gas blow channel and the first uniform flow space can be formed between the inner circumferential wall of the position-limiting ring structure and the outer circumferential wall of the base. The gas flow channel structure can be formed between the base and the carrier element. The gas flow channel structure can be configured to transfer the purge gas to the first uniform flow space via the connection flow channel in the base. The first uniform flow space can be configured to uniform the purge gas. The uniformed purge gas can be blown out from the gas blow channel to purge the bottom surface and the side surface of the wafer. The purge gas can be uniformed by the first uniform flow space to cause the gas blow channel to blow the gas uniformly to ensure that the edge purging can have the consistent effect on the bottom surface and the side surface of the wafer. Thus, the consistency of the processing formed film can be greatly improved, and the yield can be greatly improved. In addition, the gas blow channel and the first uniform space can be formed between the base and the position-limiting ring structure. The gas flow channel structure can be formed between the base and the carrier element. The structure of the carrier device can be simple and easy to manufacture. Thus, the application and manufacturing costs can be greatly reduced.

Based on the same invention concept, embodiments of the present disclosure provide semiconductor processing equipment, including a processing chamber and the carrier device above. For example, as shown in FIG. 4A, the carrier device (including but is not limited to the base 1 and the carrier element 2) is arranged in the processing chamber 7 and configured to carry the wafer.

In the semiconductor processing equipment of embodiments of the present disclosure, by adopting the above carrier device, the manufacturing cost can be reduced, and the consistency of the processing formed film can be improved. Thus, the yield can be greatly improved.

The above embodiments are merely exemplary embodiments used to describe the present disclosure. However, the present disclosure is not limited to this. For those ordinary skill in the art, various variations and improvements can be made to embodiments of the represent disclosure without departing from the spirit and essence of the present disclosure. These variations and improvements are within the scope of the present disclosure.

In the description of embodiments of the present disclosure, orientational or positional relationship indicated by terms such as “center,” “upper,” “lower,” “front,” “back,” “left,” “right,” “vertical,” “horizontal,” “top,” “bottom,” “inner,” and “outer,” are based on the orientational or positional relationship shown in the drawings. The terms are only used to facilitate the description of embodiments the present disclosure and simplify the description, rather than indicating or implying that the device or element referred to must have a specific orientation and be constructed and operated in a specific orientation. Therefore, the terms cannot be understood as a limitation to the present disclosure.

In addition, the terms “first” and “second” are only used for descriptive purposes and cannot be understood as indicating or implying relative importance or implicitly indicating the number of indicated technical features. Thus, a feature as associated with “first” and “second” may explicitly or implicitly include one or more of the features. In the description of the present disclosure, “a plurality of” means two or more than two, unless otherwise specifically defined.

In the description of embodiments of the present disclosure, the terms “mount,” “connection,” and “coupling” should be understood in a broad sense. For example, the terms may indicate a fixed connection, a detachable connection, an integral connection, a direct connection, an indirect connection through an intermediary, or internal communication of two components. Those of ordinary skill in the art should understand the specific meanings of the above terms in embodiments of the present disclosure according to specific situations.

In the description of the present disclosure, features, structures, materials, or characteristics can be combined in a suitable manner in any one or more embodiments of examples.

The above are merely some embodiments of the present disclosure. For those ordinary skill in the art, without departing from the principle of the present disclosure, improvements and modifications can be made. These improvements and modifications are within the scope of the present disclosure.

What is claimed is:

1. A carrier device applied to semiconductor processing equipment comprising:
a base including a connection flow channel, a top surface of the base being configured to carry a wafer;
a carrier element stacked with the base and located under the base, a gas flow channel structure being formed between the carrier element and the base; and
a position-limiting ring structure sleeved at an outer circumference of the base and configured to limit a position of the wafer, a gas blow cannel and a first uniform flow space being formed between an inner circumferential wall of the position-limiting ring structure and an outer circumferential wall of the base, the first uniform flow space communicating with the gas blow channel;
wherein:
the gas flow channel structure communicates with the first uniform flow space via the connection flow channel and is configured to transfer a purge gas to the first uniform flow space via the connection flow channel;
the first uniform flow space is configured to uniform the purge gas passing by; and
the gas blow channel is configured to blow the uniformed purge gas to purge a bottom surface and a side surface of the wafer.

2. The carrier device according to claim 1, wherein the gas flow channel structure includes:
a guide flow channel structure; and
a second uniform flow space communicating with the guide flow channel structure and communicating with the first uniform form space via the connection flow channel;
wherein:
the guide flow channel structure is configured to transfer the purge gas to the second uniform flow space; and
the second uniform flow space is configured to uniform the purge gas flowing by.

3. The carrier device according to claim 2, wherein:
a volume of the second uniform flow space is greater than a volume of the first uniform flow space; and/or
a gas introduction cross-section of the connection flow channel is smaller than gas introduction cross-sections of the first uniform flow space and the second uniform flow space.

4. The carrier device according to claim 2, wherein the connection flow channel includes:
a plurality of flow-limiting holes passing through the base and arranged uniformly along a circumferential direction of the base, two ends of each flow-limiting hole communicating with the first uniform flow space and the second uniform flow space, respectively.

5. The carrier device according to claim 4, wherein each flow-limiting hole includes:
a first straight hole and a second straight hole arranged sequentially in a vertical direction, the first straight hole being arranged above the second straight hole, and a diameter of the first straight hole being smaller than a diameter of the second straight hole.

6. The carrier device according to claim 2, wherein the guide flow channel structure includes:
at least a guide flow channel; and
at least a gas through-hole passing through the carrier element, each gas through-hole communicating with an inlet end of the at least one guide flow channel and being configured to communicate with a purge gas source, outlet ends of guide flow channels being arranged uniformly along a circumferential direction of the second uniform flow space at intervals and communicate with the second uniform flow space.

7. The carrier device according to claim 6, wherein:
an annular groove and a plurality of straight grooves are formed on one of a surface of the carrier element facing the base and a surface of the base facing the carrier element, the other one of the surface carrier element facing the base and the surface of the base facing the carrier element cooperating with the annular groove to form the second uniform flow space and cooperate with each straight groove to form the guide flow channel; or
annular grooves and a plurality of straight grooves are formed on both the surface of the carrier element facing the base and the surface of the base facing the carrier element, the annular groove of the carrier element and the annular groove of the base cooperate to form the second uniform flow space, and the plurality of straight grooves of the carrier device cooperate with the plurality of straight grooves of the base to form the guide flow channels.

8. The carrier device according to claim 6, further comprising:
a support shaft located under the carrier element and configured to support the carrier element, a first uniform flow channel structure being formed on a surface of the support shaft facing the support element, and the inlet ends of the first uniform flow channel structure communicating with the inlet ends of the gas through-holes and communicating with the purge gas source.

9. The carrier device of claim 8, wherein the first uniform flow channel structure includes:
at least one first curved flow channel extending along a circumferential direction of the support shaft and corresponding to two gas through-holes, inlet ends of the two gas through-holes communicating with two ends of the first curved flow channel, and an inlet opening communicating with the purge gas source being arranged at the center position of the first curved flow channel.

10. The carrier device of claim 8, wherein:
the base also includes a plurality of first absorption holes passing through the base arranged uniformly along a circumferential direction of the base;
the carrier element also includes a plurality of second absorption holes passing through the carrier element, a number of the second absorption holes being same as a number of the first absorption holes, and the plurality of second absorption holes being in a one-to-one correspondence with the plurality of first absorption holes;
a second uniform flow channel structure is further formed on a surface of the support shaft facing the carrier element, and communicates correspondingly with inlet ends of the second absorption holes and a vacuum absorption device.

11. The carrier device according to claim 10, wherein:
the second uniform flow channel structure includes at least one second curved flow channel extending along a circumferential direction of the support shaft;
each second curved flow channel corresponds to two second absorption holes;
inlet ends of two second absorption holes communicate with two ends of the second curved flow channel, respectively; and
an inlet opening communicating with the vacuum absorption device is formed at a center position of the second curved flow channel.

12. The carrier device according to claim 11, wherein:
two second curved flow channels are provided and are symmetrically distributed about an axis of the support shaft;
the second uniform flow channel structure also includes a third curved flow channel extending along a circumferential direction of the support shaft;
two ends of the third curved flow channel communicate with two second curved flow channels at center positions of the two second curved flow channels, respectively; and
the third curved flow channel communicates with the vacuum absorption device at a center position of the third curved flow channel.

13. The carrier device according to claim 1, wherein:
the position-limiting ring structure includes a ring body;
a cover ring protruding toward an outer circumferential wall of the base is formed at an inner circumferential wall of the ring body; and
a gap between the inner circumferential wall of the cover ring and the outer circumferential wall of the base forms the gas blow channel.

14. The carrier device according to claim 13, wherein:
a guide flow groove is formed at a connection place between a top surface and an inner circumferential surface of the cover ring;
the guide flow groove is annular and surrounds a circumferential direction of the cover ring;
a bottom surface of the guide flow groove is lower than the top surface of the base;
a diameter of a circumferential side surface of the guide flow groove is greater than a diameter of the wafer; and
the guide flow groove communicates with the gas blow channel and is configured to guide the purge gas from the gas blow channel to a bottom surface and a side surface of the wafer.

15. The carrier device according to claim 13, wherein:
the base includes a base body;
a carrier ring protruding toward an inner circumferential wall of the ring body is arranged at the outer circumferential wall of the base body;
an overlap ring protruding toward the base body is arranged at the inner circumferential wall of the ring body and below the cover ring; and
the overlap ring is stacked on the carrier ring, and a gap between the overlap ring and the outer circumferential wall of the base body forms the first uniform flow space.

16. The carrier device according to claim 15, wherein:
a positioning structure is arranged between two surfaces of the overlap ring and the carrier ring that are stacked with each other; and
the positioning structure includes a positioning convex member and a positioning recess member; and
the positioning convex member cooperates with the positioning recess member to limit a relative position between the overlap ring and the carrier ring.

17. The carrier device according to claim 15, wherein:
a protruded flow-limiting ring is formed at the outer referential wall of the base body and located between the carrier ring and the cover ring;
a gap between the flow-limiting ring and the cover ring forms a flow-limiting channel configured to communicate the gas blow channel with the first uniform flow space.

18. The carrier device according to claim 17, wherein:
a gas introduction cross-section of the position-limiting channel is smaller than a gas introduction cross-section of the gas blow channel;
the gas introduction cross-section of the gas blow channel is smaller than the gas introduction cross-section of the first uniform flow space; and
the gas introduction cross-section of the connection flow channel is greater than the gas introduction cross-section of the flow-limiting channel.

19. The carrier device according to claim 1, wherein the base, the carrier element, and the position-limiting ring structure are made of aluminum nitride ceramic.

20. Semiconductor processing equipment comprising:
a processing chamber; and
a carrier device arranged in the processing chamber and comprising:
a base including a connection flow channel, a top surface of the base being configured to carry a wafer;
a carrier element stacked with the base and located under the base, a gas flow channel structure being formed between the carrier element and the base; and
a position-limiting ring structure sleeved at an outer circumference of the base and configured to limit a position of the wafer, a gas blow cannel and a first uniform flow space being formed between an inner circumferential wall of the position-limiting ring structure and an outer circumferential wall of the base, the first uniform flow space communicating with the gas blow channel;
wherein:
the gas flow channel structure communicates with the first uniform flow space via the connection flow channel and is configured to transfer a purge gas to the first uniform flow space via the connection flow channel;
the first uniform flow space is configured to uniform the purge gas passing by; and
the gas blow channel is configured to blow the uniformed purge gas to purge a bottom surface and a side surface of the wafer.
